(19) United States
(12) Patent Application Publication
(10) Pub. No.: US 2009/0066656 A1
(43) Pub. Date: Mar. 12, 2009

(54) METHOD AND APPARATUS FOR INPUTTING KOREAN CHARACTERS BY USING TOUCH SCREEN

(75) Inventors: Jong-woo JUNG, Seoul (KR); Young-wan SEO, Yongin-si (KR); Il-ku CHANG, Seoul (KR); Ho-kyung KIM, Seongnam-si (KR); Shannu JIANG, Seongnam-si (KR)

Correspondence Address: STEIN, MCEWEN & BUI, LLP, 1400 EYE STREET, NW, SUITE 300, WASHINGTON, DC, 20005, US

(73) Assignee: SAMSUNG ELECTRONICS CO., LTD., Suwon-si (KR)

(21) Appl. No.: 12/203,476

(22) Filed: Sep. 3, 2008

(30) Foreign Application Priority Data
Sep. 6, 2007 (KR) 2007-90583

(51) Int. Cl. G06F 3/02; H03K 17/94

(52) U.S. Cl. 345/171; 341/28

(57) ABSTRACT

A method and apparatus to inputt Korean characters using a touch screen, the method including: if a first input that selects a consonant key displayed on the touch screen is sensed, vowel keys including a Cheon (•) key, a Ji (-) key, and an In (┐) key are displayed around the selected consonant key; and, if a second input that selects at least one of the displayed vowel keys is sensed, a consonant corresponding to the first input is determined as an initial character of a syllable and a vowel corresponding to the second input is determined as a medial character of the syllable.

### CROSS-REFERENCE TO RELATED APPLICATION

This application claims the benefit of Korean Patent Application No. 2007-90583, filed Sep. 6, 2007, in the Korean Intellectual Property Office, the disclosure of which is incorporated herein by reference.

### BACKGROUND OF THE INVENTION

1. Field of the Invention

Aspects of the present invention relate to a method and apparatus for inputting Korean characters by using a touch screen, and more particularly, to a method and apparatus for inputting vowels of Korean characters on a touch screen by using the Cheon(•) Ji(-) In(|) method.

2. Description of the Related Art

As touch screens are now more widely used in various mobile devices as well as in other devices to perform simple operations, various methods of inputting characters on the touch screens have become popular. In order to realize various operations of mobile devices, characters are input to the mobile devices. Thus, a faster and more efficient method of inputting characters is expected for mobile devices using touch screens.

Conventional methods of inputting characters on a touch screen include a method of using a virtual keyboard through which consonant keys and vowel keys are simply arranged, and a method of recognizing a user's handwriting as graphics of characters.

Korean characters are more complicated than other alphabets because at least two phonemes of Koreans characters are arranged in two directions in order to form a syllable while most other alphabets are simply arranged and input in one direction. That is, while most other alphabets are arranged one by one, a plurality of phonemes form a syllable in Korean characters. Thus, the method of using a virtual keyboard is not feasible to input Korean characters. Also, a virtual key-board arranges fixed keys that can not support diversities in user input patterns.

Furthermore, in the method of recognizing a user's handwriting, directions and shapes of the Korean characters input on the touch screen may be different according to users so that the user's handwriting may not be easily or accurately recognized.

Accordingly, when Korean characters are input on a touch screen by using a conventional method, speed and accuracy of inputting the Korean characters are lower than the speed and accuracy of inputting other alphabets, thereby reducing a usability of the touch screen.

### SUMMARY OF THE INVENTION

Aspects of the present invention provide a method and apparatus for inputting Korean characters on a touch screen in which an arrangement of consonant keys on a virtual key-board is simplified and an arrangement of vowel keys is designed appropriately for the touch screen by using the Cheon(•) Ji(-) In(|) method so as to improve speed and efficiency of inputting the Korean characters. Aspects of the present invention also provide a method of inputting Korean characters on a touch screen in which a phoneme may be selected by touching the touch screen with a touch tool or a plurality of phonemes may be sequentially selected so as to improve speed and efficiency of inputting the Korean characters.

According to an aspect of the present invention, there is provided a method of inputting Korean characters by using a touch screen, the method including: if a first input that selects a consonant key displayed on the touch screen is sensed, displaying vowel keys including a Cheon (•) key, a Ji (-) key, and an In (┐) key around the selected consonant key; and, if a second input that selects at least one of the displayed vowel keys is sensed, determining a consonant corresponding to the first input as an initial character of a syllable and determining a vowel corresponding to the second input as a medial character of the syllable.

The method may further include displaying, on the touch screen, predetermined consonant keys that correspond to consonants having corresponding double consonants, on the touch screen; and, if the selected consonant is one of the predetermined consonant keys, displaying a double consonant key corresponding to the selected consonant key around the selected consonant key.

The method may further include inactivating other consonant keys, except for the selected consonant key, when the vowel keys are displayed on the touch screen.

The second input may be sensed when a touch tool or a user's finger is sequentially dragged on at least one combination of the vowel keys.

If a third input that selects at least one of the consonant keys is sensed after the second input is sensed, the determining may further include determining a consonant corresponding to the third input as a final character of the syllable.

If a touch tool or a user's finger is not separated from the touch screen for a predetermined period of time after the second input is sensed, the inactivating of the other consonant keys may further include reactivating the other consonant keys, and if a third input that selects at least one of the activated consonant keys is sensed, the determining may further include determining a consonant corresponding to the third input as a final character of the syllable.

The determining may include determining that a current key and a next key are sequentially input if the current key is selected by using a touch tool or a user's finger that is touched on and then separated from the touch screen, and then the next key is selected by using the touch tool or the user's finger that is touched on the touch screen again within a predetermined period of time.

The determining may include determining that a current key and a next key are sequentially input if the current key is selected by using a touch tool or a user's finger that is touched on the touch screen and the touch tool or the user's finger is dragged to the next key, without being separated from the touch screen, and is paused on the next key for a predetermined period of time.

The determining may include determining that a current key and a next key are sequentially input if the current key is selected by a touch tool or a user's finger that is touched on the touch screen and the touch tool or the user's finger reaches the next key by being dragged through a region outside input key regions, without being separated from the touch screen.

The determining may further include determining that a syllable is completely input if a current key is selected by using a touch tool or a user's finger that is touched on and separated from the touch screen, and then the touch tool or the user's finger touches a region outside input key regions of the touch screen.

The determining may further include determining that a syllable is completely input if a current key is selected by using a touch tool or a user's finger that is touched on the touch screen and the touch tool or the user's finger is dragged to a region outside input key regions of the touch screen and is paused for a predetermined period of time.

The determining may further include determining that a syllable is completely input, when a touch tool or a user's finger is sequentially dragged on and used to select a plurality of input keys including a current key, if the touch tool or the user's finger is used to select the current key and then is separated from the touch screen.

According to another aspect of the present invention, there is provided an apparatus to input Korean characters by using a touch screen, the apparatus including: a vowel key display unit to, if a first input that selects a consonant key displayed on the touch screen is sensed, display vowel keys including a Cheon (•) key, a Ji (-) key, and an In (┐) key around the selected consonant key; and a determination unit to, if a second input that selects at least one of the displayed vowel keys is sensed, determine a consonant corresponding to the first input as an initial character of a syllable and to determine a vowel corresponding to the second input as a medial character of the syllable.

According to another aspect of the present invention, there is provided a computer readable recording medium having recorded thereon a computer program for executing the above-described method and implemented by at least one computer.

According to yet another aspect of the present invention, there is provided a method of inputting characters using a touch screen, the method including: displaying second types of keys if a first input that selects a first type of key displayed on the touch screen is sensed; and determining a first type of character corresponding to the first input as an initial character of a syllable and determining a second type of character corresponding to a second input as a medial character of the syllable if the second input selecting at least one displayed second type of character is sensed.

According to still another aspect of the present invention, there is provided a method of inputting characters using a touch screen, the method including: displaying second types of keys if an input that selects a first type of key displayed on the touch screen is sensed, wherein the first type of key corresponds to a first type of character and the second types of keys correspond to a second type of character.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become more apparent and more readily appreciated from the following description of the embodiments, taken in conjunction with the accompanying drawings of which:

FIG. 1 is a block diagram of an apparatus for inputting Korean characters by using a touch screen, according to an embodiment of the present invention;

FIG. 2 is a diagram illustrating an arrangement of consonants on a touch screen for inputting Korean characters, according to an embodiment of the present invention;

FIG. 3A is a diagram illustrating an arrangement of basic consonants on a touch screen for inputting Korean characters, according to an embodiment of the present invention;

FIG. 3B is a diagram illustrating an arrangement of double consonants and vowels on a touch screen for inputting Korean characters, according to an embodiment of the present invention;

FIG. 4A is a diagram for describing a method of inputting a vowel of a syllable made of Korean characters by using the touch screen illustrated in FIG. 2, according to an embodiment of the present invention;

FIG. 4B is a diagram for describing a method of inputting a double consonant and a vowel of a syllable made of Korean characters by using the touch screen illustrated in FIGS. 3A and 3B, according to an embodiment of the present invention;

FIG. 5 is a diagram for describing a method of inputting a final character of a syllable made of Korean characters by using the touch screen illustrated in FIGS. 3A and 3B, according to an embodiment of the present invention; and

FIG. 6 is a flowchart of a method of inputting Korean characters by using a touch screen, according to an embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

FIG. 1 is a block diagram of an apparatus 100 to input Korean characters using a touch screen 150, according to an embodiment of the present invention. Referring to FIG. 1, the apparatus 100 includes a sensing unit 110, a vowel key display unit 120, a determination unit 130, and the touch screen 150 to receive data from and output data to. The apparatus 100 may be, or may be included in, any system to which Korean characters are input.

The sensing unit 110 senses an input on the touch screen 150 and outputs information regarding which key is selected to the vowel key display unit 120. If a first input that selects a consonant key displayed on the touch screen 150 is sensed by the sensing unit 110, the vowel key display unit 120 displays an instruction to display vowel keys including a Cheon (•) key, a Ji (|) key, and an In (-) key around the selected consonant key. If a second input that selects at least one vowel key displayed on the touch screen 150 is sensed by the sensing unit 110, the determination unit 130 determines the consonant corresponding to the first input as an initial character of a syllable and determines the vowel corresponding to the second input as a medial character of the syllable so as to output a determined syllable.

According to aspects of the present invention, the syllable determined by the determination unit 130 may be output to any unit of the apparatus 100 that uses information on the determined syllable (such as a central processing unit (CPU) or the touch screen 150). Furthermore, according to aspects of the present invention, if a third input that selects at least one consonant key is sensed by the sensing unit 110 after the second input is sensed, the determination unit 130 determines a consonant corresponding to the third input as a final character of the syllable.

The determination unit 130 may determine a sequential input in various ways. For example, if the sensing unit 110 senses that a current key is selected by a touch tool or a user's finger on the touch screen 150 then separated therefrom, and a next key is selected by the touch tool or the user's finger on the touch screen 150 again within a predetermined period of time, the determination unit 130 may determine that the current and next keys are sequentially input. Also, if the sensing unit 110 senses that a current key is selected by a touch tool or a user's finger on the touch screen 150 and the touch tool or the user's finger is dragged to a next key, without being separated from the touch screen 150, and is paused on the next key for a predetermined period of time, the determination unit 130 may also determine that the current and next keys are sequentially input. According to another embodiment, if the sensing unit 110 senses that a current key is selected by a touch tool or a user's finger on the touch screen 150 and the touch tool or the user's finger reaches a next key by being dragged through a region outside input key regions, without being separated from the touch screen 150, the determination unit 130 may also determine that the current and next keys are sequentially input.

Although not shown in FIG. 1, according to another embodiment of the present invention, the apparatus 100 may further include a double consonant key display unit that displays a double consonant key corresponding to a consonant key that is selected if the sensing unit 110 senses that a consonant corresponding to the consonant key is selected from among consonants that have corresponding double consonants.

In order to input a double consonant, according to an embodiment of the present invention, the double consonant may be selected according to a number of a selecting operation that sequentially selects a consonant key of a consonant having a corresponding double consonant.

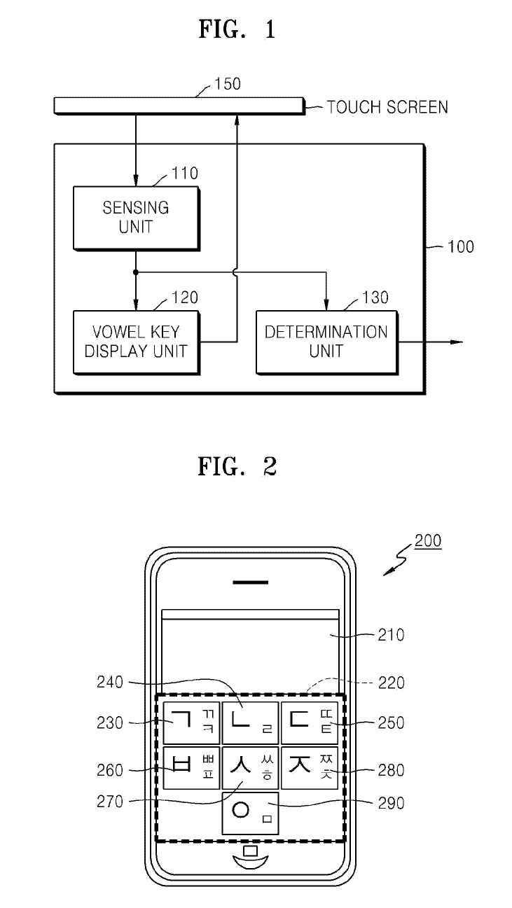

Operations of the vowel key display unit 120, the double consonant key display unit, and the determination unit 130 will now be described in detail with reference to FIGS. 2, 3A, 3B, 4A, 4B, and 5. FIGS. 2, 3A, 3B, 4A, 4B, and 5 will be described in conjunction with FIG. 1.

FIG. 2 is a diagram illustrating an arrangement of consonants on a touch screen 200 to input Korean characters, according to an embodiment of the present invention. Referring to FIG. 2, the touch screen 200 includes a character display unit 210 and an input key unit 220. The input key unit 220 includes basic consonant keys such as a “ [symbol] ” key 230, a “ [symbol] ” key 240, a “ [symbol] ” key 250, a “ [symbol] ” key 260, a “ [symbol] ” key 270, a “ [symbol] ” key 280, and a “ [symbol] ” key 290. According to the current embodiment, a consonant set including similar consonants is allocated to a basic consonant key. In more detail, consonants “ [symbol] ” are allocated to the “ [symbol] ” key 230. Likewise, consonants “ [symbol] ” “ [symbol] ” “ [symbol] ” and “ [symbol] ” are respectively allocated to the “ [symbol] ” key 250, the “ [symbol] ” key 260, the “ [symbol] ” key 270, and the “ [symbol] ” key 280. Furthermore, consonants “ [symbol] ” are allocated to the “ [symbol] ” key 240 and consonants “ [symbol] ” are allocated to the “ [symbol] ” key 290.

A selected consonant from among a plurality of consonants allocated to each basic consonant key is determined in accordance with a number of a selecting operation that sequentially selects the basic consonant key. For example, if the sensing unit 110 senses that the “ [symbol] ” key 230 is selected once, the determination unit 130 determines that the consonant “ [symbol] ” is input. If the sensing unit 110 senses that the “ [symbol] ” key 230 is selected twice or three times, the determination unit 130 determines that the consonant “ [symbol] ” or the consonant “ [symbol] ” is input, respectively.

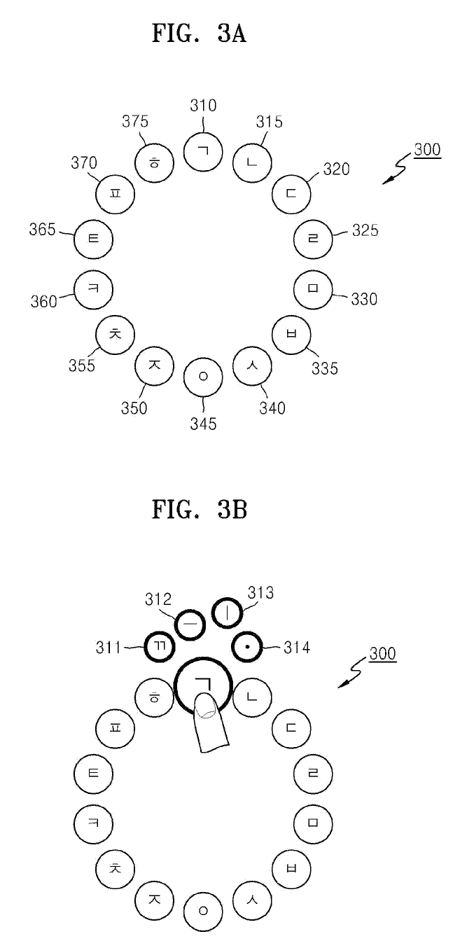

FIG. 3A is a diagram illustrating an arrangement of basic consonants on a touch screen 300 to input Korean characters, according to an embodiment of the present invention. Referring to FIG. 3A, the touch screen 300 includes a “ [symbol] ” key 310, a “ [symbol] ” key 315, a “ [symbol] ” key 320, a “ [symbol] ” key 325, a “▭” key 330, a “ [symbol] ” key 335, a “ [symbol] ” key 340, a “ [symbol] ” key 345, a “ [symbol] ” key 350, a “ [symbol] ” key 355, a “ [symbol] ” key 360, a “ [symbol] ” key 365, a “ [symbol] ” key 370, and a “ [symbol] ” key 375. If the sensing unit 110 senses an input in which one of the basic consonant keys 310, 315, 320, 325, 330, 335, 340, 345, 350, 355, 360, 365, 370, and 375 is selected, the determination unit 130 determines a consonant corresponding to the selected basic consonant key as an initial character or a final character of a syllable.

FIG. 3B is a diagram illustrating an arrangement of double consonants and vowels on a touch screen 300 to input Korean characters, according to an embodiment of the present invention. Referring to FIG. 3B, if the sensing unit 110 senses an input in which one of the basic consonant keys 310, 315, 320, 325, 330, 335, 340, 345, 350, 355, 360, 365, 370, and 375 (illustrated in FIG. 3A) is selected, the vowel key display unit 120 displays vowel keys including a Cheon (•) key 312, a Ji (-) key 313, and an In (|) key 314 on the touch screen 300. Although the vowel keys 312, 313, and 314 are illustrated in FIG. 3B as being around the selected basic consonant key on the touch screen 300, it is understood that aspects of the present invention are not limited thereto. For example, according to other aspects, the vowel keys 312, 313, and 314 may be displayed on a designated portion (such as a top or a bottom) of the touch screen 300, or in a vertical or horizontal line.

If a basic consonant key corresponding to a basic consonant having a corresponding double consonant is selected, a double consonant key display unit displays a double consonant key corresponding to the double consonant on the touch screen 300. For example, the double consonant key display unit may display the double consonant key next to the selected basic consonant key, together with the vowel keys. For example, if a “ [symbol] ” key 310 is selected, a “ [symbol] ” key 311 is displayed next to the “ [symbol] ” key 310. Accordingly, if a basic consonant key corresponding to a basic consonant having a corresponding double consonant is selected, a double consonant key corresponding to the double consonant, the Cheon (•) key 312, the Ji (-) key 313, and the In (|) key 314 may be displayed around the selected basic consonant key on the touch screen 300.

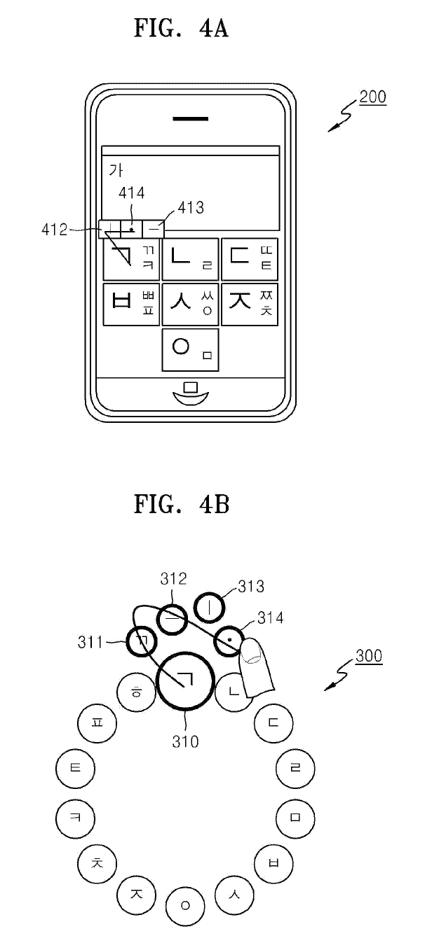

FIG. 4A is a diagram to describe a method of inputting a vowel of a syllable made of Korean characters by using the touch screen 200 illustrated in FIG. 2, according to an embodiment of the present invention. Referring to FIG. 4A, if the sensing unit 110 senses an input of a basic consonant key on the touch screen 200, the vowel key display unit 120 displays the vowel keys including a Cheon (•) key 414, a Ji (-) key 413, and an In (|) key 412 around the selected basic consonant key on the touch screen 200.

Accordingly, the determination unit 130 determines a first input of the selected basic consonant key as an initial character of a syllable and determines a second input of a vowel key as a medial character of the syllable. Vowels are input by using a Cheon (•) Ji (-) In (|) method and, thus, the vowels are input by one or a combination of the Cheon (•) key 414, the Ji (-) key 413, and the In (|) key 412. For example, if the In (|) key 412 and the Cheon (•) key are sequentially input, a vowel “ [symbol] ” is input. Likewise, if the Cheon (•) key is input twice and then the In (|) key 412 is input once, sequentially, a vowel “ [symbol] ” is input. Accordingly, if a “ [symbol] ” key is input as the first input and then the In (|) key 412 and the Cheon (•) key are sequentially input as the second input, a syllable “ [symbol] ” is input.

As described above with reference to FIG. 1, the determination unit 130 may determine a sequential input in various ways. Accordingly, if a sequential input of the “ [symbol] ” key, the In (|) key 412, and the Cheon (•) key corresponds to any of the sequential input methods, the determination unit 130 determines that the syllable “ [symbol] ” is input.

Specifically, a current key may be selected by a touch tool or a user's finger on the touch screen 200 and then separated therefrom, and then a next key may be selected by the touch tool or the user's finger on the touch screen 200 again within a predetermined period of time. Alternatively, a current key may be selected by a touch tool or a user's finger on the touch screen 200 and the touch tool may be dragged to a next key, without being separated from the touch screen 200, and paused on the next key for a predetermined period of time. Also, a current key may be selected by a touch tool or a user's finger on the touch screen 200 and the touch tool or the user's finger may reach a next key by being dragged through a region outside input key regions, without being separated from the touch screen 200. However, it is understood that aspects of the present invention are not limited to the abovementioned sequential input methods.

FIG. 4B is a diagram for describing a method of inputting a double consonant and a vowel of a syllable made of Korean characters by using the touch screen 300 illustrated in FIGS. 3A and 3B, according to an embodiment of the present invention. Referring to FIG. 4B, a method of inputting an initial character and a medial character of a syllable will be described by assuming that all basic consonant keys are displayed on the touch screen 300 and, if a consonant having a corresponding double consonant is selected, a double consonant key corresponding to the double consonant, and vowel keys are displayed around the selected basic consonant key.

If the basic consonant “ [symbol] ” key 310, an In (|) key 314, and a Cheon (•) key 312 are sequentially selected, a syllable “ [symbol] ” is input. In order to input a double consonant “ [symbol] ” as an initial character of a syllable, the “ [symbol] ” key 310 is selected and then a “ [symbol] ” key 311 is selected. Accordingly, if the “ [symbol] ” key 311, the In (|) key 314, and the Cheon (•) key 312 are sequentially selected, a syllable “ [symbol] ” is input. The determination unit 130 may also determine a sequential input in various ways as described above with reference to FIG. 4A.

According to aspects of the present invention, if a basic consonant key is selected and vowel keys are displayed around the selected basic consonant key on the touch screen 200 illustrated in FIG. 2, the apparatus 100 includes an activation control unit (not shown) that may inactivate other basic consonant keys, except for the selected basic consonant key. According to other aspects of the present invention, if vowel keys are generated on the touch screen 300 illustrated in FIGS. 3A and 3B, the activation control unit may inactivate all the basic consonant keys.

FIG. 5 is a diagram for describing a method of inputting a final character of a syllable made of Korean characters by using the touch screen 300 illustrated in FIGS. 3A and 3B, according to an embodiment of the present invention. Referring to FIG. 5, according to aspects of the present invention, consonant keys may be inactivated after vowel keys are generated by an activation control unit (not shown) of the apparatus 100. If a touch tool or a user's finger is not separated from the touch screen 300 for a predetermined period of time after a vowel is selected as a second input, the activation control unit may then activate the consonant keys in order to input the final character.

If a third input that selects at least one of the consonant keys is sensed after the second input is sensed by the sensing unit 110, the determination unit 130 determines a consonant corresponding to the third input as a final character of the syllable. For example, all basic consonant keys are displayed by being separated from each other on the touch screen 300 and thus the touch tool or the user's finger may be dragged on the touch screen 300 to a desired consonant, without selecting a double consonant key after selecting a vowel key. The determination unit 130 may also determine a sequential input in various ways as described above with reference to FIG. 4A.

The determination unit 130 may determine that a syllable is completely input in a variety of ways. For example, if the sensing unit 110 senses that a current key is selected by a touch tool or a user's finger on the touch screen 300 and separated therefrom, and then the touch tool or the user's finger touches a region outside input key regions, the determination unit 130 may determine that a syllable is completely input. Furthermore, if the sensing unit 110 senses that a current key is selected by a touch tool or a user's finger on the touch screen 300 and the touch tool or the user's finger is dragged to a region outside input key regions and is paused for a predetermined period of time, the determination unit 130 may determine that a syllable is completely input. Also, when a touch tool or a user's finger is sequentially dragged on and used to select a plurality of input keys including a current key, if the sensing unit 110 senses that the touch tool or the user's finger is used to select the current key and then is separated from the touch screen 300, the determination unit 130 may determine that a syllable is completely input. Accordingly, a syllable may be completely input after selecting desired input keys. However, it is understood that aspects of the present invention are not limited to the abovementioned complete input methods.

If the determination unit 130 determines that a syllable is completely input, the apparatus 100 activates the basic consonant keys or is converted to a basic consonant key input screen in order to input a first input for a next syllable.

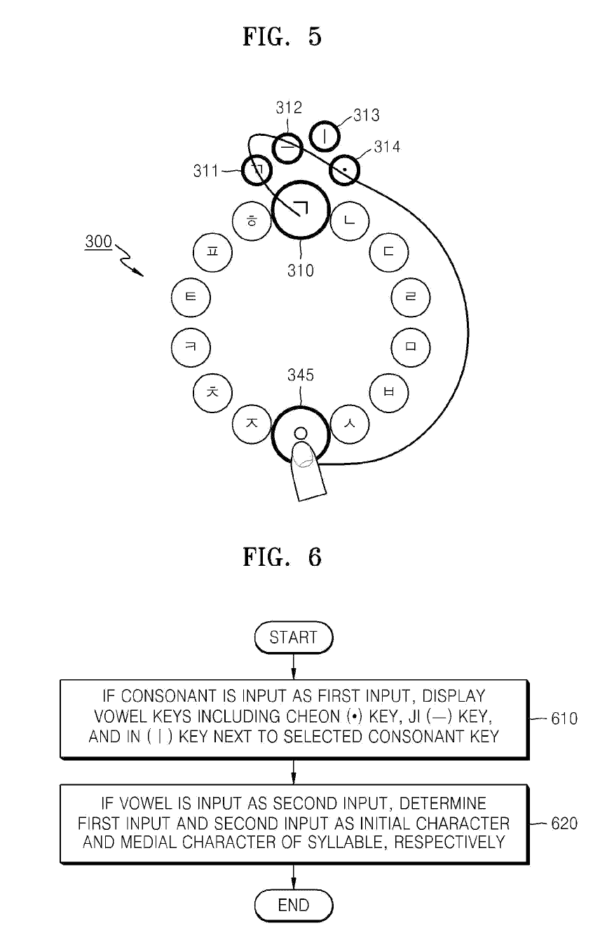

FIG. 6 is a flowchart of a method of inputting Korean characters by using a touch screen, according to an embodiment of the present invention. Referring to FIG. 6, if a first input that selects a consonant key displayed on the touch screen is sensed, vowel keys including a Cheon (•) key, a Ji (-) key, and an In (┐) key are displayed around the selected consonant key in operation 610. If the vowel keys are displayed on the touch screen, the consonant keys may be inactivated, although aspects of the present invention are not limited thereto.

If a second input that selects at least one of the displayed vowel keys is sensed, a consonant corresponding to the first input is determined as an initial character of a syllable and a vowel corresponding to the second input is determined as a medial character of the syllable in operation 620.

Assuming that the consonant keys are inactivated after the vowel keys are displayed on the touch screen, the consonant keys may be reactivated after the vowel corresponding to the second input is selected in order for a third input corresponding to a final character of the syllable to be sensed.

According to aspects of the present invention, if a touch tool or a user's finger is separated from the touch screen or if the touch tool or the user's finger touches a region outside of input key regions and is paused for a predetermined period of time, the apparatus 100 illustrated in FIG. 1 may determine that a syllable is completely input.

While aspects of the present invention have been described in relation to Korean language characters, it is understood that other aspects can be applied to other languages.

Aspects of the present invention can be written as computer programs and can be implemented in general-use digital computers that execute the programs using a computer-readable recording medium. Examples of the computer-readable recording medium include magnetic storage media (e.g., ROM, floppy disks, hard disks, etc.), and optical recording media (e.g., CD-ROMs, or DVDs). Aspects of the present invention may also be realized as a data signal embodied in a carrier wave and comprising a program readable by a computer and transmittable over the Internet.

As described above, according to aspects of the present invention, a user may input Korean characters on a touch screen quickly and efficiently. Instead of arranging all consonant keys and all vowel keys on a touch screen as in a conventional virtual keyboard, only currently used keys are appropriately arranged on the touch screen according to aspects of the present invention. Thus, usability of the space of the touch screen is improved and the user may use the touch screen more efficiently while inputting Korean characters. Also, characters may be input by using a dragging method as well as a conventional clicking method using a touch tool or a user's finger and thus a user may continuously input one syllable at a time without being interrupted, as if the user is actually writing with a pen. Thus, fast inputting of Korean characters is enabled. Furthermore, an interface that is changeable according to operations of a user may be configured by using a key arrangement method and a sequential input method, thus increasing convenience and interest for users.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A method of inputting Korean characters using a touch screen, the method comprising:
displaying vowel keys including a Cheon (•) key, a Ji (-) key, and an In (┐) key around a consonant key if a first input that selects the consonant key displayed on the touch screen is sensed; and
determining a consonant corresponding to the first input as an initial character of a syllable and determining a vowel corresponding to a second input as a medial character of the syllable if the second input selecting at least one displayed vowel key is sensed.

2. The method as claimed in claim 1, further comprising:
displaying, on the touch screen, predetermined consonant keys that correspond to consonants having corresponding double consonants; and
displaying a double consonant key corresponding to the consonant key selected by the first input if the selected consonant key is one of the predetermined consonant keys.

3. The method as claimed in claim 2, wherein the displaying of the double consonant key comprises displaying the double consonant key around the selected consonant key.

4. The method as claimed in claim 1, further comprising inactivating other consonant keys, except for the selected consonant key, when the vowel keys are displayed on the touch screen.

5. The method as claimed in claim 1, wherein the second input is sensed when a touch tool or a user's finger is sequentially dragged on at least one combination of the vowel keys.

6. The method as claimed in claim 1, wherein the determining comprises:
determining a consonant corresponding to a third input as a final character of the syllable if the third input selecting at least one of the consonant keys is sensed after the second input is sensed.

7. The method as claimed in claim 4, wherein:
the inactivating of the other consonant keys comprises reactivating the other consonant keys if a touch tool or a user's finger is not separated from the touch screen for a predetermined period of time after the second input is sensed; and
the determining comprises determining a consonant corresponding to a third input as a final character of the syllable if the third input selecting at least one of the reactivated consonant keys is sensed.

8. The method as claimed in claim 4, wherein the inactivating of the other consonant keys comprises reactivating the other consonant keys if a touch tool or a user's finger is not separated from the touch screen for a predetermined period of time after the second input is sensed.

9. The method as claimed in claim 1, wherein the determining comprises:
determining that the first input and the second input are sequential if the consonant key is selected by using a touch tool or a user's finger on the touch screen and then separated therefrom, and the at least one vowel key is then selected by using the touch tool or the user's finger on the touch screen within a predetermined period of time; and
determining the consonant as the initial character and the vowel as the medial character of the syllable if the first input and the second input are determined to be sequential.

10. The method as claimed in claim 1, wherein the determining comprises:
determining that the first input and the second input are sequential if the consonant key is selected by using a touch tool or a user's finger that is touched on the touch screen and the touch tool or the user's finger is dragged to the at least one vowel key, without being separated from the touch screen, and is paused on the at least one vowel key for a predetermined period of time; and
determining the consonant as the initial character and the vowel as the medial character of the syllable if the first input and the second input are determined to be sequential.

11. The method as claimed in claim 1, wherein the determining comprises:
determining that the first input and the second input are sequential if the consonant key is selected by a touch tool or a user's finger that is touched on the touch screen and the touch tool or the user's finger reaches the at least one vowel key by being dragged through a region outside input key regions of the touch screen, without being separated from the touch screen; and
determining the consonant as the initial character and the vowel as the medial character of the syllable if the first input and the second input are determined to be sequential.

12. The method as claimed in claim 1, wherein the determining comprises determining that the syllable is completely input if a current key is selected by using a touch tool or a user's finger that is touched on and separated from the touch screen, and then the touch tool or the user's finger touches a region outside input key regions of the touch screen.

13. The method as claimed in claim 1, wherein the determining comprises determining that the syllable is completely input if a current key is selected by using a touch tool or a user's finger that is touched on the touch screen and the touch tool or the user's finger is dragged to a region outside input key regions of the touch screen and is paused for a predetermined period of time in the region outside the input key regions.

14. The method as claimed in claim 1, wherein the determining comprises determining that the syllable is completely input when a touch tool or a user's finger is sequentially dragged on and used to select a plurality of input keys including a current key, if the touch tool or the user's finger is used to select the current key and then is separated from the touch screen.

15. An apparatus to input Korean characters using a touch screen, the apparatus comprising:
a vowel key display unit to display vowel keys including a Cheon (•) key, a Ji (-) key, and an In (┐) key around the key if a first input that selects the consonant key displayed on the touch screen is sensed; and
a determination unit to determine a consonant corresponding to the first input as an initial character of a syllable and to determine a vowel corresponding to a second input as a medial character of the syllable, if the second input selecting at least one of the displayed vowel keys is sensed.

16. The apparatus as claimed in claim 15, further comprising a double consonant key display unit to display, on the touch screen, predetermined consonant keys that correspond to consonants having corresponding double consonants, and to display a double consonant key corresponding to the consonant key selected by the first input if the selected consonant key is one of the predetermined consonant keys.

17. The apparatus as claimed in claim 16, wherein the double consonant key display unit displays the double consonant key around the selected consonant key.

18. The apparatus as claimed in claim 15, further comprising an activation control unit to inactivate other consonant keys, except for the selected consonant key, when vowel key display unit displays the vowel keys on the touch screen.

19. The apparatus as claimed in claim 15, wherein the second input is sensed when a touch tool or a user's finger is sequentially dragged on at least one combination of the vowel keys.

20. The apparatus as claimed in claim 15, wherein the determination unit determines a consonant corresponding to a third input as a final character of the syllable if the third input selecting at least one of the consonant keys is sensed after the second input is sensed.

21. The apparatus as claimed in claim 18, wherein:
the activation control unit reactivates the other consonant keys if a touch tool or a user's finger is not separated from the touch screen for a predetermined period of time after the second input is sensed; and
the determination unit determines a consonant corresponding to a third input as a final character of the syllable if the third input selecting at least one of the reactivated consonant keys is sensed.

22. The apparatus as claimed in claim 18, wherein the activation control unit reactivates the other consonant keys if a touch tool or a user's finger is not separated from the touch screen for a predetermined period of time after the second input is sensed.

23. The apparatus as claimed in claim 15, wherein:
the determination unit determines that the first input and the second input are sequential if the consonant key is selected by using a touch tool or a user's finger on the touch screen and then separated therefrom, and the at least one vowel key is then selected by using the touch tool or the user's finger that is touched on the touch screen again a predetermined period of time; and
the determination unit determines the consonant as the initial character and the vowel as the medial character of the syllable if the first input and the second input are determined to be sequential.

24. The apparatus as claimed in claim 15, wherein:
the determination unit determines that the first input and the second input are sequential if the consonant key is selected by using a touch tool or a user's finger on the touch screen and the touch tool or the user's finger is dragged to the at least one vowel key, without being separated from the touch screen, and is paused on the at least one vowel key for a predetermined period of time; and
the determination unit determines the consonant as the initial character and the vowel as the medial character of the syllable if the first input and the second input are determined to be sequential.

25. The apparatus as claimed in claim 15, wherein:
the determination unit determines that the first input and the second input are sequential if the consonant key is selected by using a touch tool or a user's finger on the touch screen and the touch tool or the user's finger reaches the at least one vowel key by being dragged through a region outside input key regions of the touch screen, without being separated from the touch screen; and
the determination unit determines the consonant as the initial character and the vowel as the medial character of the syllable if the first input and the second input are determined to be sequential.

26. The apparatus as claimed in claim 15, wherein the determination unit determines that the syllable is completely input if a current key is selected by a touch tool or a user's finger that is touched on and separated from the touch screen, and then the touch tool or the user's finger touches a region outside input key regions of the touch screen.

27. The apparatus as claimed in claim 15, wherein the determination unit determines that the syllable is completely input if a current key is selected by a touch tool or a user's finger that is touched on the touch screen and the touch tool or the user's finger is dragged to a region outside input key regions of the touch screen and is paused for a predetermined period of time in the region outside the input key regions.

28. The apparatus as claimed in claim 15, wherein the determination unit determines that the syllable is completely input when a touch tool or a user's finger is sequentially dragged on and used to select a plurality of input keys including a current key, if the touch tool or the user's finger is used to select the current key and then is separated from the touch screen.

29. A computer readable recording medium having recorded thereon a computer program for executing the method of claim 1 and implemented by at least one computer.
